(19) United States
(12) Patent Application Publication
(10) Pub. No.: US 2023/0314475 A1
(43) Pub. Date: Oct. 5, 2023

(54) PROBE STRUCTURE

(71) Applicant: CHOON LEONG LOU, Singapore (SG)

(72) Inventor: CHOON LEONG LOU, Singapore (SG)

(21) Appl. No.: 17/889,143

(22) Filed: Aug. 16, 2022

(30) Foreign Application Priority Data
Mar. 29, 2022 (TW) 111111988

(51) Int. Cl. G01R 1/067; G01R 31/28

(52) U.S. Cl. CPC G01R 1/06738; G01R 31/2886

(57) ABSTRACT

The present disclosure provides a probe structure. The probe structure includes a plurality of bodies and a plurality of protrusions. Each body includes an end portion. Each end portion has a surface. The plurality of protrusions are formed on the surfaces and extend toward a same direction. At least one protrusion is formed on each surface.

### CROSS REFERENCE TO RELATED APPLICATION

This application claims priority of Taiwan application No. 111111988 filed on Mar. 29, 2022, which is incorporated by reference in its entirety.

### TECHNICAL FIELD

The present disclosure relates to a probe and, more particularly, to a probe structure comprising a plurality of probe bodies.

### DISCUSSION OF THE BACKGROUND

During a manufacturing process of a conventional integrated circuit (IC) chip, the IC chip undergoes electrical testing. To facilitate such testing, the IC chip includes a solder ball or solder bump functioning as an electrode portion. Furthermore, an oxidized film that covers the electrode portion must be removed in order to ensure good electrical connection between the electrode portion and a probe used in the electrical testing. The oxidized film is perforated with a sharp end portion of the probe to ensure good contact.

However, the probe deforms when it contacts the IC chip under test. To mitigate the deformation of the probe and thus ensure the structural strength of the probe's body, the conventional probe body includes a spiral spring. Such spiral spring has several drawbacks, including (1) poor transmission of electrical signals, (2) unsteady direction of electric current, and (3) low resilience to wear and tear.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

A probe structure according to an embodiment of the present disclosure includes: a plurality of bodies, each body including an end portion with a surface; and a plurality of protrusions formed on the surfaces and extending in a same direction, wherein at least one protrusion is formed on each surface.

In some embodiments, the plurality of bodies include a first body and a second body contiguous with the first body.

In some embodiments, the plurality of protrusions include a first protrusion and a second protrusion, the first protrusion is formed on the surface of the end portion of the first body, and the second protrusion is formed on the surface of the end portion of the second body.

In some embodiments, the plurality of protrusions include a first protrusion, a second protrusion and a third protrusion, the first protrusion is formed on the surface of the end portion of the first body, the second protrusion being formed on the surface of the end portion of the second body, and the third protrusion is formed on the surface of the end portion of the second body.

In some embodiments, the plurality of protrusions include a first protrusion, a second protrusion, a third protrusion and a fourth protrusion, the first protrusion and the second protrusion are formed on the surface of the end portion of the first body, and the third protrusion and the fourth protrusion are formed on the surface of the end portion of the second body.

In some embodiments, the plurality of bodies include a first body, a second body and a third body, and the first body, the second body and the third body are contiguous with each other.

In some embodiments, the plurality of bodies include a first body, a second body and a third body, and the first body and the second body are each contiguous with the third body.

In some embodiments, the plurality of protrusions include a first protrusion, a second protrusion, a third protrusion and a fourth protrusion, the first protrusion is formed on the surface of the end portion of the first body, the second protrusion is formed on the surface of the end portion of the second body, the third protrusion being formed on the surface of the end portion of the third body, and the fourth protrusion is formed on the surface of the end portion of the third body.

In some embodiments, each body is contiguous with at least two others of the bodies.

In some embodiments, each protrusion has a sharp end.

In some embodiments, vertices of the sharp ends of the plurality of protrusions define a plane, and the plane is parallel to one or more of the surfaces.

In some embodiments, each protrusion extends in a direction perpendicular to a corresponding one of the surfaces.

Another embodiment of the present disclosure provides a probe structure comprising: a first body having a first contact end with a first surface; a second body having a second contact end with a second surface; at least a first sharp end formed on the first surface and extending in a direction; and at least a second sharp end formed on the second surface and extending in the direction, wherein a vertex of the at least a first sharp end and a vertex of the at least a second sharp end are colinear or coplanar, such that a line or a plane defined by the vertex of the at least a first sharp end and the vertex of the at least a second sharp end is parallel to the first surface and the second surface.

In some embodiments, toward to an opposite direction of the direction, the line or the plane casts a projection image on the first surface and the second surface, such that the projection image overlaps the first surface and the second surface.

In some embodiments, the first body and the second body are contiguous.

The technical features and advantages of the present disclosure are comprehensively provided in the description above, so as to enable better understanding of the present disclosure from details given in the description below. Additional technical features and advantages forming the subject matter of the claims of present disclosure are provided in the description below. A person skilled in the art of the present disclosure should understand that it would be easy to implement objects same as those of the present disclosure by modifying or designing of other structures or processes on the basis of the concept and specific embodiments disclosed in the description below. Moreover, a person skilled in the art should understand that such equivalent arrangements are to be encompassed within the spirit and scope of the present disclosure as defined by the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1A is a perspective view of a probe structure according to some embodiments of the present disclosure.

FIG. 1B is a top view of the probe structure according to some embodiments of the present disclosure.

FIG. 2A is a perspective view of a probe structure according to some embodiments of the present disclosure.

FIG. 2B is a top view of the probe structure according to some embodiments of the present disclosure.

FIG. 2C is a top view of the probe structure according to some embodiments of the present disclosure.

FIG. 3A is a perspective view of a probe structure according to some embodiments of the present disclosure.

FIG. 3B is a top view of the probe structure according to some embodiments of the present disclosure.

FIG. 4A is a perspective view of a probe structure according to some embodiments of the present disclosure.

FIG. 4B is a top view of the probe structure according to some embodiments of the present disclosure.

FIG. 5A is a perspective view of a probe structure according to some embodiments of the present disclosure.

FIG. 5B is a top view of the probe structure according to some embodiments of the present disclosure.

FIG. 6A is a perspective view of a probe structure according to some embodiments of the present disclosure.

FIG. 6B is a top view of the probe structure according to some embodiments of the present disclosure.

FIG. 7A is a perspective view of a probe structure according to some embodiments of the present disclosure.

FIG. 7B is a top view of the probe structure according to some embodiments of the present disclosure.

FIG. 8A is a perspective view of a probe structure according to some embodiments of the present disclosure.

FIG. 8B is a top view of the probe structure according to some embodiments of the present disclosure.

### DETAILED DESCRIPTION

The description of the present disclosure below is accompanied by drawings forming a part of the description to illustrate embodiments of the present disclosure. However, it should be noted that the present disclosure is not limited to these embodiments. Moreover, the embodiments below can be appropriately integrated into another embodiment.

The terms “embodiment,” “an embodiment,” “exemplary embodiment,” “other embodiment” and “another embodiment” mean that the embodiments described in the present disclosure can include specific features, structures or characteristics; however, it should be noted that not every embodiment needs to include such specific features, structures or characteristics. In addition, repeated use of the expression “in the embodiment” or “of the embodiment” does not necessarily refer to the same embodiment, but may refer to the same embodiment.

To fully understand the present disclosure, steps and structures are described in detail below. It should be obvious that implementation of the present disclosure does not limit specific details generally known to persons skilled in the art. Further, generally known structures and steps are not described in detail, so as to prevent unnecessary limitation to the present disclosure. Preferred embodiments of the present disclosure are described in detail below. However, apart from the detailed description, the present disclosure can also be extensively applied in other embodiments. The scope of the present disclosure is not limited to the contents given in the detailed description, but is to be defined in accordance with the appended claims.

It should be understood that the disclosure below provides various different embodiments or implementation examples for implementing different features of the present disclosure. Specific embodiments or implementation examples of components and arrangements are set forth below to simplify the present disclosure. It should be noted that such details are exemplary and are not to be intended to be restrictive. For example, a size of an element is not limited to a disclosed range or value, but can depend on an expected property of a manufacturing condition and/or device. Moreover, in the description below, a first feature described as formed “on” or “above” a second feature may include embodiments in which the first feature and the second feature are formed in a direct contact manner, and may also include embodiments in which an additional feature is formed between the first feature and the second feature in a way that the first feature and the second feature may not be in direct contact. For simplicity and clarity, various features may be depicted according to different scales. In the accompanying drawings, some layers/features are omitted for the sake of simplicity.

Moreover, for better illustration, terms of relative spatial relations such as “beneath,” “below,” “lower,” “above” and “upper” may be used to describe a relation of one element or feature relative to another element or feature. Such terms of relative spatial relations are intended to cover different orientations of the element during use or operation in addition to the orientation depicted in the drawings. An apparatus may be orientated otherwise (rotated 90 degrees or having another orientation) and the descriptive terms of the relative spatial relations used in the literature may also be similarly and correspondingly interpreted.

The adjective “sharp” is hereunder used to describe the shape of a component, for the sole purpose of shape comparison. The words “sharp end” used hereunder are not intended to place limitations on a shape of an end portion of a probe structure. The technical feature “end portion” will not depart from the scope of the shape of the probe structure of the present disclosure, provided that the end portion is effective in perforating an oxidized film of an object under test.

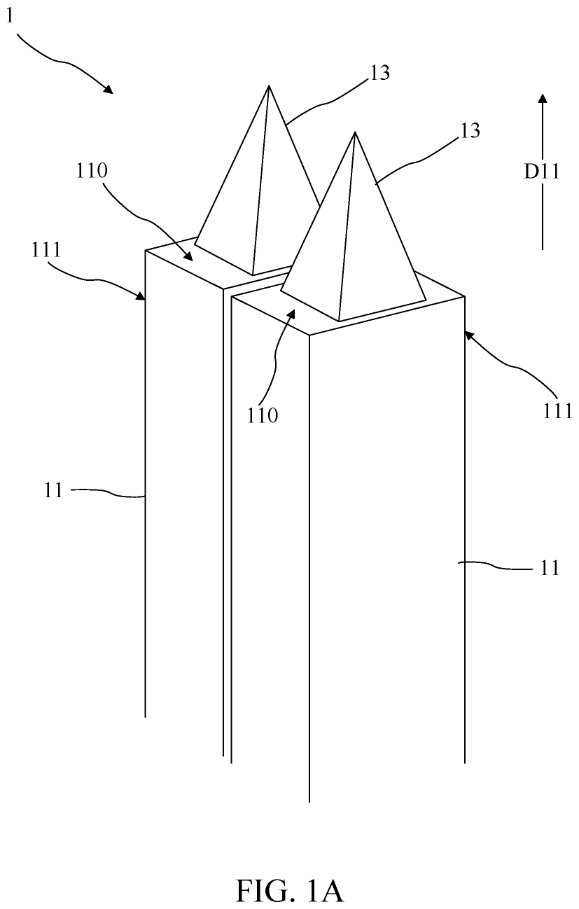

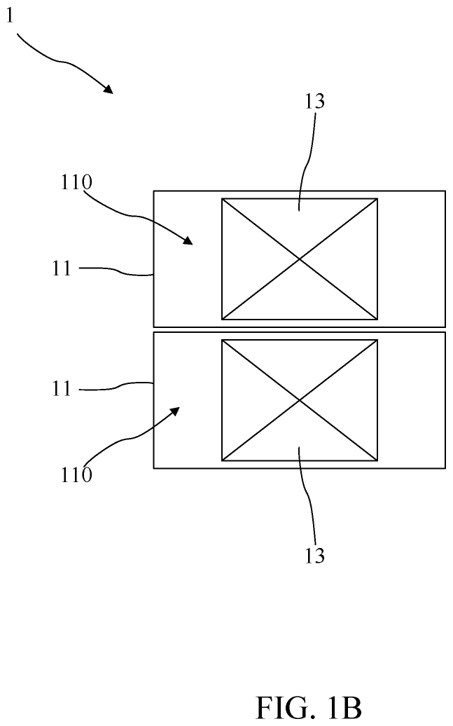

Referring to FIG. 1A and FIG. 1B, FIG. 1A is a perspective view of a probe structure 1 according to some embodiments of the present disclosure, and FIG. 1B is a top view of the probe structure 1 according to some embodiments of the present disclosure. The probe structure 1 comprises a plurality of bodies 11 and a plurality of protrusions 13. Each body 11 comprises an end portion 111. Each end portion 111 has a surface 110. The plurality of protrusions 13 are formed on the surfaces 110 and extend in a direction D11. At least one protrusion 13 is formed on each surface 110. In some embodiments, the protrusion 13 is formed on each surface 110 and adapted to contact an object under test (not shown), for example, an integrated circuit (IC) chip.

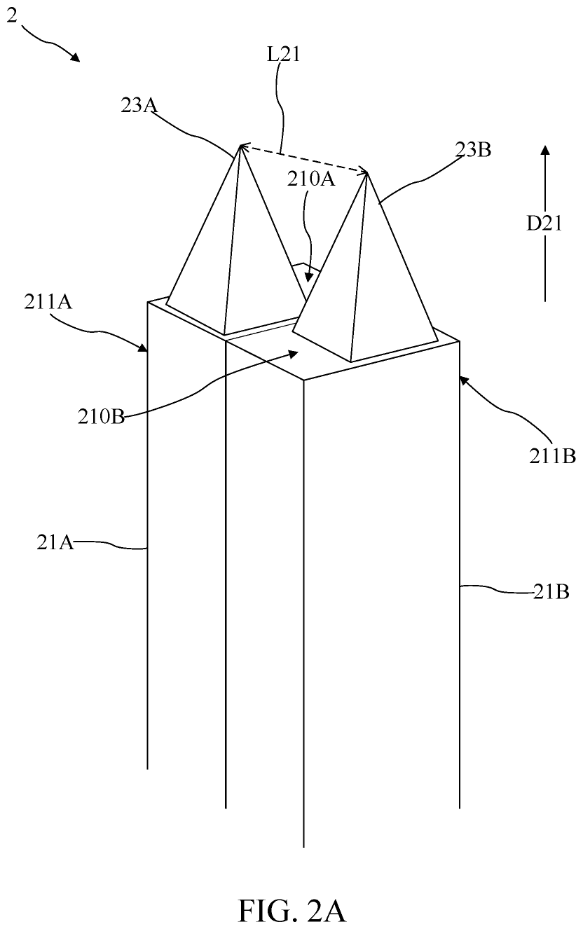

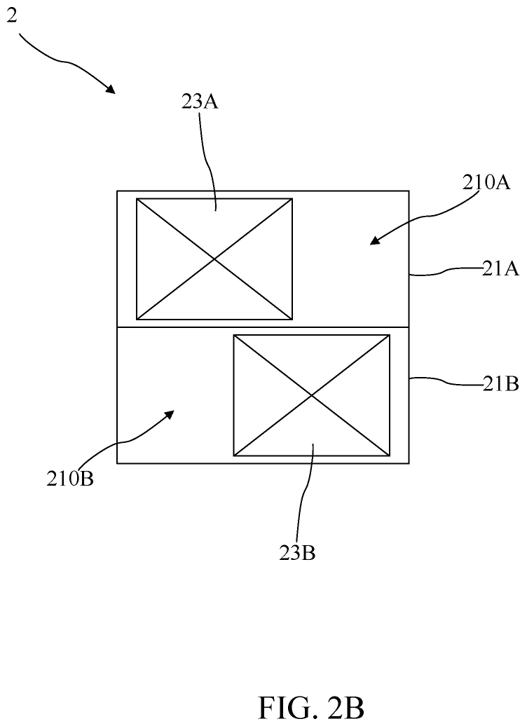

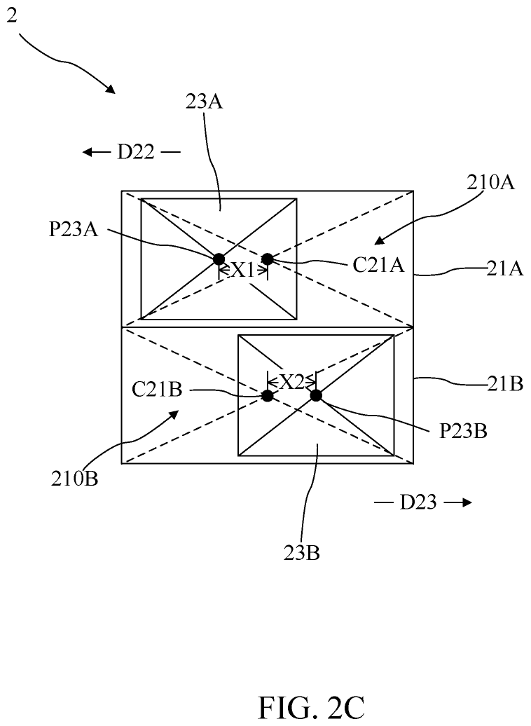

Referring to FIG. 2A and FIG. 2B, FIG. 2A is a perspective view of a probe structure 2 according to some embodiments of the present disclosure, and FIG. 2B is a top view of the probe structure 2 according to some embodiments of the present disclosure. The probe structure 2 comprises a first body 21A, a second body 21B, a first protrusion 23A and a second protrusion 23B. The first body 21A comprises an end portion 211A. The end portion 211A has a surface 210A. The first protrusion 23A is formed on the surface 210A and extends in a direction D21. The second body 21B comprises an end portion 211B. The end portion 211B has a surface 210B. The second protrusion 23B is formed on the surface 210B and extends in the direction D21. In some embodiments, the first protrusion 23A and the second protrusion 23B are adapted to contact an object under test (not shown), for example, an IC chip.

In some embodiments, the first body 21A and the second body 21B are contiguous. A minimum distance between the first body 21A and the second body 21B is greater than or equal to zero, and is less than or equal to a specific numeric value.

In some embodiments, the minimum distance between the first body 21A and the second body 21B is equal to zero. In some embodiments, when the minimum distance between the first body 21A and the second body 21B is equal to a specific numeric value, a maximum width of the probe structure 2 is less than a structural width of conventional probe bodies.

Referring to FIG. 2C, FIG. 2C is a top view of the probe structure 2 according to some embodiments of the present disclosure. A projection point P23A formed by projecting an endpoint of the first protrusion 23A onto the surface 210A is separated from a center C21A of the surface 210A by a distance X1. A projection point P23B formed by projecting an endpoint of the second protrusion 23B onto the surface 210B is separated from a center C21B of the surface 210B by a distance X2. The projection point P23A is shifted in a direction D22 relative to the center C21A. The projection point P23B is shifted in a direction D23 opposite to the direction D22 relative to the center C21B.

In some embodiments, vertices of the first protrusion 23A and the second protrusion 23B are colinear and define a line L21 parallel to the surfaces 210A and 210B. Thus, a shortest distance between the surface 210A and the vertex of the first protrusion 23A is equal to a shortest distance between the surface 210B and the vertex of the second protrusion 23B. The surface 210A and the surface 210B are coplanar.

In some embodiments, toward to an opposite direction of the direction D21, a projection image of the line L21 falls on the surface 210A and the surface 210B (i.e., the line L1 casts the projection image on the surface 210A and the surface 210B). Thus, the projection image of the line L21 falls in a direction opposite to the direction D21 onto the surface 210A and the surface 210B. Therefore, the projection image of the line L21 overlaps the surface 210A and the surface 210B.

In some embodiments, when the probe structure 2 is adapted to contact a specific area to be tested on an object under test, a center of the line L21 defined by the vertices of the first protrusion 23A and the second protrusion 23B can be directed toward the center of the specific area to be tested, such that the center of the line L21 overlaps the center of the specific area to be tested. Therefore, when the first protrusion 23A and the second protrusion 23B of the probe structure 2 contact the specific area to be tested, a force exerted on the probe structure 2 due to the contact is evenly distributed between the first protrusion 23A and the second protrusion 23B.

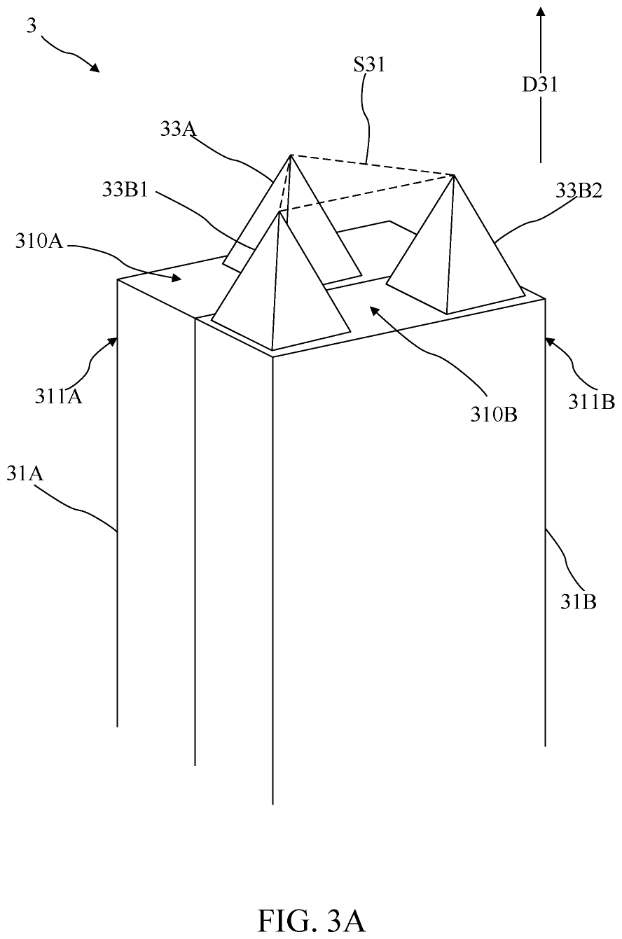

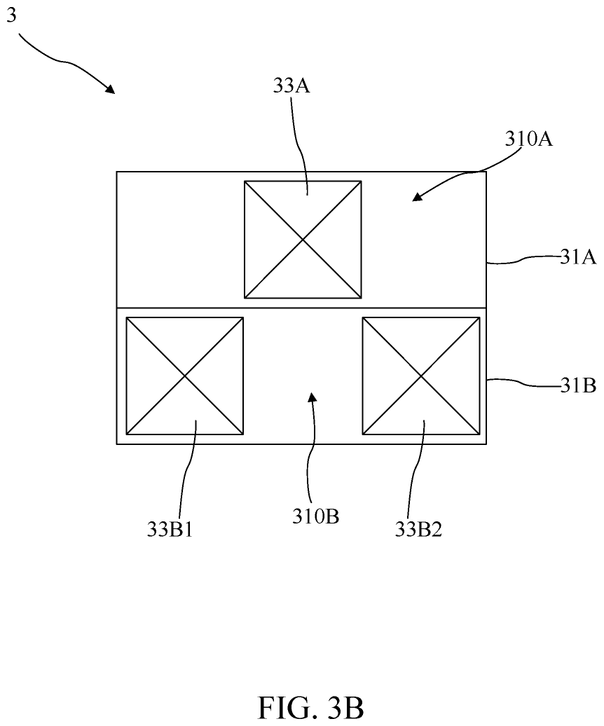

Referring to FIG. 3A and FIG. 3B, FIG. 3A is a perspective view of a probe structure 3 according to some embodiments of the present disclosure, and FIG. 3B is a top view of the probe structure 3 according to some embodiments of the present disclosure. The probe structure 3 comprises a first body 31A, a second body 31B, a first protrusion 33A, a second protrusion 33B1 and a third protrusion 33B2. The first body 31A comprises an end portion 311A. The end portion 311A has a surface 310A. The first protrusion 33A is formed on the surface 310A and extends in a direction D31. The second body 31B comprises an end portion 311B. The end portion 311B has a surface 310B. The second protrusion 33B1 and the third protrusion 33B2 are formed on the surface 310B and extend in the direction D31. In some embodiments, the protrusions 33A, 33B1 and 33B2 are adapted to contact an object under test (not shown), for example, an IC chip.

In some embodiments, the first body 31A and the second body 31B are contiguous. A minimum distance between the first body 31A and the second body 31B is greater than or equal to zero, and is less than or equal to a specific numeric value. In some embodiments, the minimum distance between the first body 31A and the second body 31B is equal to zero. In some embodiments, when the minimum distance between the first body 31A and the second body 31B is equal to a specific numeric value, a maximum width of the probe structure 3 is less than the structural width of conventional probe bodies.

In some embodiments, vertices of the first protrusion 33A, the second protrusion 33B1 and the third protrusion 33B2 are coplanar and define a plane S31 parallel to the surfaces 310A and 310B. Thus, a shortest distance between the surface 310A and the vertex of the first protrusion 33A, a shortest distance between the surface 310B and the vertex of the second protrusion 33B1, and a shortest distance between the surface 310B and the vertex of the third protrusion 33B2 are equal. The surface 310A and the surface 310B are coplanar.

In some embodiments, toward to an opposite direction of the direction D31, a projection image of the plane S31 falls on the surface 310A and the surface 310B (i.e., the plane S31 cast the projection image on the surface 310A and the surface 310B). Thus, the projection image of the plane S31 falls in a direction opposite to the direction D31 onto the surface 310A and the surface 310B. Therefore, the projection image of the plane S31 overlaps the surface 310A and the surface 310B.

In some embodiments, when the probe structure 3 is adapted to contact a specific area to be tested on an object under test, a center of the plane S31 defined by the vertices of the first protrusion 33A, the second protrusion 33B1 and the third protrusion 33B2 can be directed toward a center of the specific area to be tested, such that the center of the plane S31 overlaps the center of the specific area to be tested. Therefore, when the first protrusion 33A, the second protrusion 33B1 and the third protrusion 33B2 of the probe structure 3 contact the specific area to be tested, a force exerted on the probe structure 3 due to the contact is evenly distributed between the first protrusion 33A, the second protrusion 33B1 and the third protrusion 33B2.

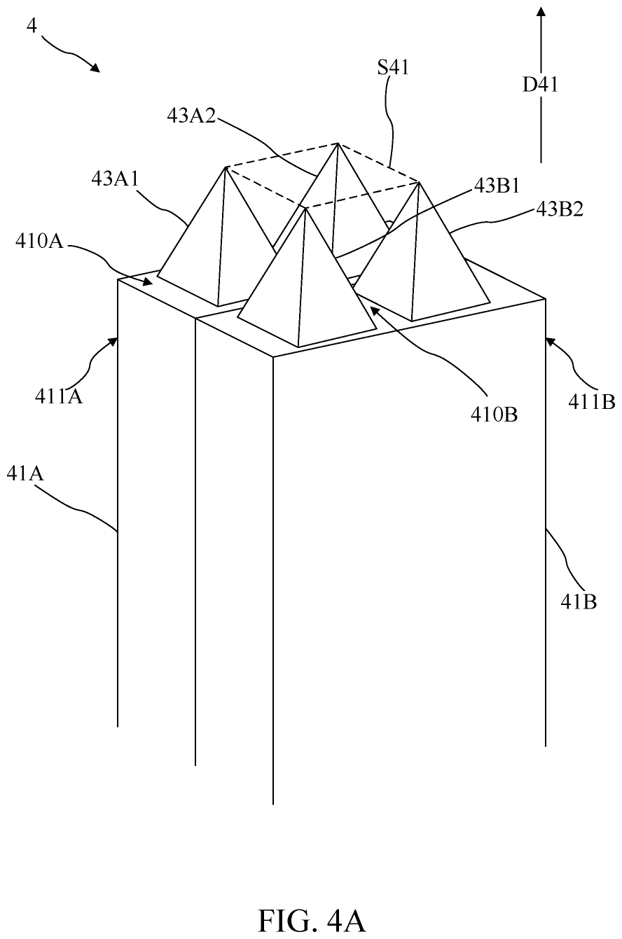

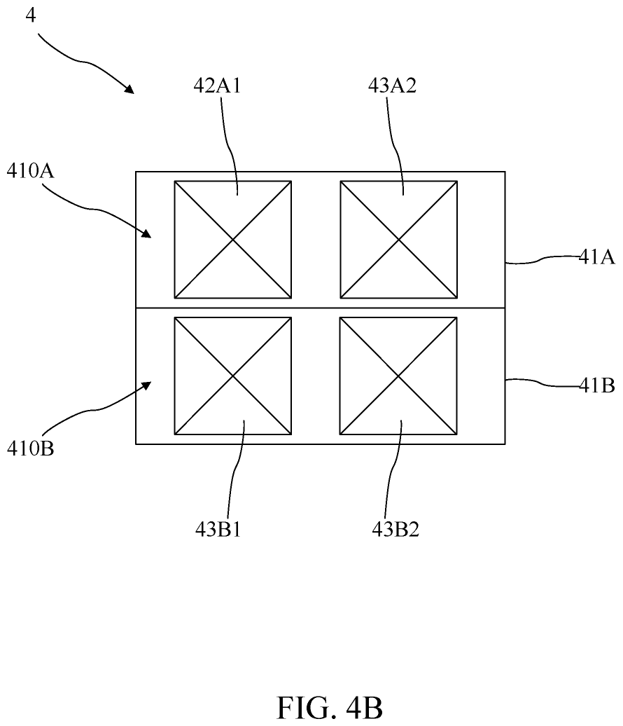

Refer to FIG. 4A and FIG. 4B, FIG. 4A is a perspective view of a probe structure 4 according to some embodiments of the present disclosure, and FIG. 4B is a top view of the probe structure 4 according to some embodiments of the present disclosure. The probe structure 4 comprises a first body 41A, a second body 41B, a first protrusion 43A1, a second protrusion 43A2, a third protrusion 43B1 and a fourth protrusion 43B2. The first body 41A comprises an end portion 411A. The end portion 411A has a surface 410A. The first protrusion 43A1 and the second protrusion 43A2 are formed on the surface 410A and extend in a direction D41. The second body 41B comprises an end portion 411B. The end portion 411B has a surface 410B. The third protrusion 43B1 and the fourth protrusion 43B2 are formed on the surface 410B and extend in the direction D41. In some embodiments, the protrusions 43A1, 43A2, 43B1 and 43B2 are adapted to contact an object under test (not shown), for example, an IC chip.

In some embodiments, the first body 41A and the second body 41B are contiguous. A minimum distance between the first body 41A and the second body 41B is greater than or equal to zero, and is less than or equal to a specific numeric value.

In some embodiments, the minimum distance between the first body 41A and the second body 41B is equal to zero. In some embodiments, when the minimum distance between the first body 41A and the second body 41B is equal to a specific numeric value, a maximum width of the probe structure 4 is less than the structural width of conventional probe bodies.

In some embodiments, vertices of the first protrusion 43A1, the second protrusion 43A2, the third protrusion 43B1 and the fourth protrusion 43B2 are coplanar and define a plane S41 parallel to the surfaces 410A and 410B. Thus, a shortest distance between the surface 410A and the vertex of the first protrusion 43A1, a shortest distance between the surface 410A and the vertex of the second protrusion 43A2, a shortest distance between the surface 410B and the vertex of the third protrusion 43B1, and a shortest distance between the surface 410B and the vertex of the fourth protrusion 43B2 are equal. The surface 410A and the surface 410B are coplanar.

In some embodiments, toward to an opposite direction of the direction D41, a projection image of the plane S41 falls on the surface 410A and the surface 410B (i.e., the plane S41 casts the projection image on the surface 410A and the surface 410B). Thus, the projection image of the plane S41 falls in a direction opposite to the direction D41 onto the surface 410A and the surface 410B. Therefore, the projection image of the plane S41 overlaps the surface 410A and the surface 410B.

In some embodiments, when the probe structure 4 is adapted to contact a specific area to be tested on an object under test, a center of the plane S41 defined by the vertices of the first protrusion 43A1, the second protrusion 43A2, the third protrusion 43B1 and the fourth protrusion 43B2 can be directed toward a center of the specific area to be tested, such that the center of the plane S41 overlaps the center of the specific area to be tested. Therefore, when the first protrusion 43A1, the second protrusion 43A2, the third protrusion 43B1 and the fourth protrusion 43B2 of the probe structure 4 contact the specific area to be tested, a force exerted on the probe structure 4 due to the contact is evenly distributed between the first protrusion 43A1, the second protrusion 43A2, the third protrusion 43B1 and the fourth protrusion 43B2.

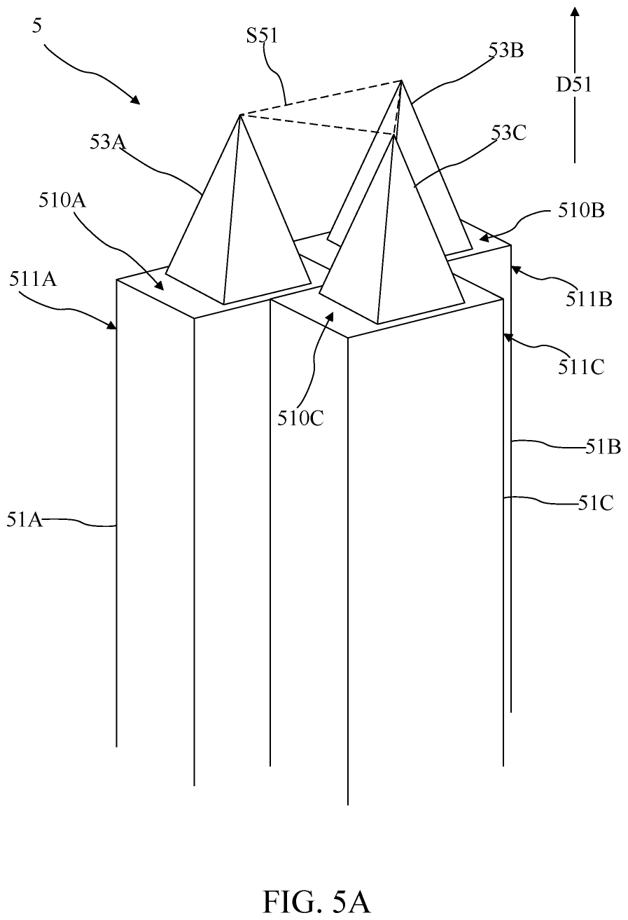

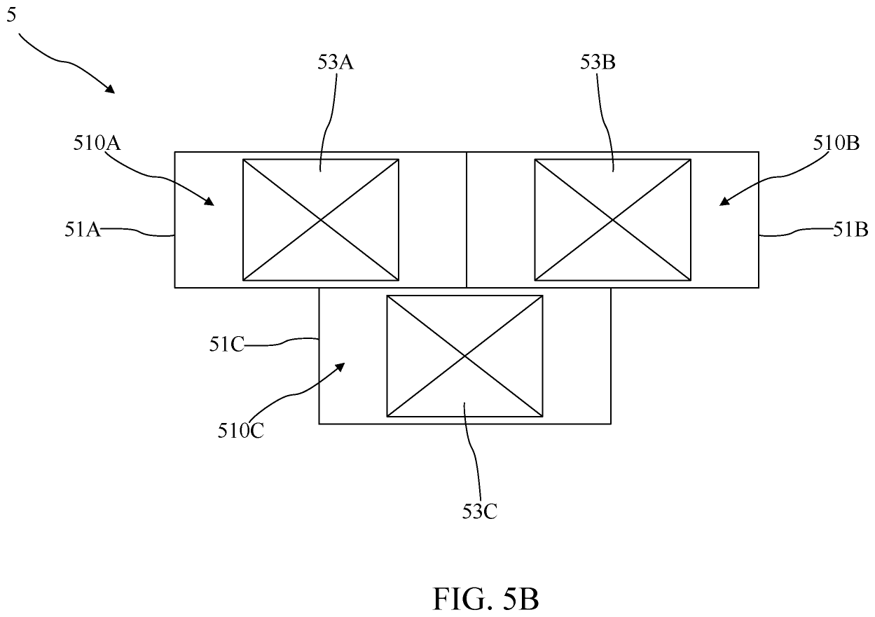

Referring to FIG. 5A and FIG. 5B, FIG. 5A is a perspective view of a probe structure 5 according to some embodiments of the present disclosure, and FIG. 5B is a top view of the probe structure 5 according to some embodiments of the present disclosure. The probe structure 5 comprises a first body 51A, a second body 51B, a third body 51C, a first protrusion 53A, a second protrusion 53B and a third protrusion 53C. The first body 51A comprises an end portion 511A. The end portion 511A has a surface 510A. The first protrusion 53A is formed on the surface 510A and extends in a direction D51. The second body 51B comprises an end portion 511B. The end portion 511B has a surface 510B. The second protrusion 53B is formed on the surface 510B and extends in the direction D51. The third body 51C comprises an end portion 511C. The end portion 511C has a surface 510C. The third protrusion 53C is formed on the surface 510C and extends in the direction D51. In some embodiments, the protrusions 53A, 53B and 53C are adapted to contact an object under test (not shown), for example, an IC chip.

In some embodiments, the first body 51A, the second body 51B and the third body 51C are contiguous with each other. A minimum distance between any two of the first body 51A, the second body 51B and the third body 51C is greater than or equal to zero, and is less than or equal to a specific numeric value. In some embodiments, the minimum distance between any two of the first body 51A, the second body 51B and the third body 51C is equal to zero. In some embodiments, when the minimum distance between any two of the first body 51A, the second body 51B and the third body 51C is equal to a specific numeric value, a maximum width of the probe structure 5 is less than the structural width of conventional probe bodies.

In some embodiments, the vertices of the first protrusion 53A, the second protrusion 53B and the third protrusion 53C are coplanar and define a plane S51 parallel to the surfaces 510A, 510B and 510C. Thus, a shortest distance between the surface 510A and the vertex of the first protrusion 53A, a shortest distance between the surface 510B and the vertex of the second protrusion 53B, and a shortest distance between the surface 510C and the vertex of the third protrusion 53C are equal. The surface 510A, the surface 510B and the surface 510C are coplanar.

In some embodiments, toward to an opposite direction of the direction D51, a projection image of the plane S51 falls on the surface 510A, the surface 510B and the surface 510C (i.e., the plane S51 casts the projection image on the surface 510A, the surface 510B and the surface 510C). Thus, the projection image of the plane S51 falls in a direction opposite to the direction D51 onto the surface 510A, the surface 510B and the surface 510C. Therefore, the projection image of the plane S51 overlaps the surface 510A, the surface 510B and the surface 510C.

In some embodiments, when the probe structure 5 is adapted to contact a specific area to be tested on an object under test, a center of the plane S51 defined by the vertices of the first protrusion 53A, the second protrusion 53B and the third protrusion 53C can be directed toward a center of the specific area to be tested, such that the center of the plane S51 overlaps the center of the specific area to be tested. Therefore, when the first protrusion 53A, the second protrusion 53B and the third protrusion 53C of the probe structure 5 contact the specific area to be tested, a force exerted on the probe structure 5 due to the contact is evenly distributed between the first protrusion 53A, the second protrusion 53B and the third protrusion 53C.

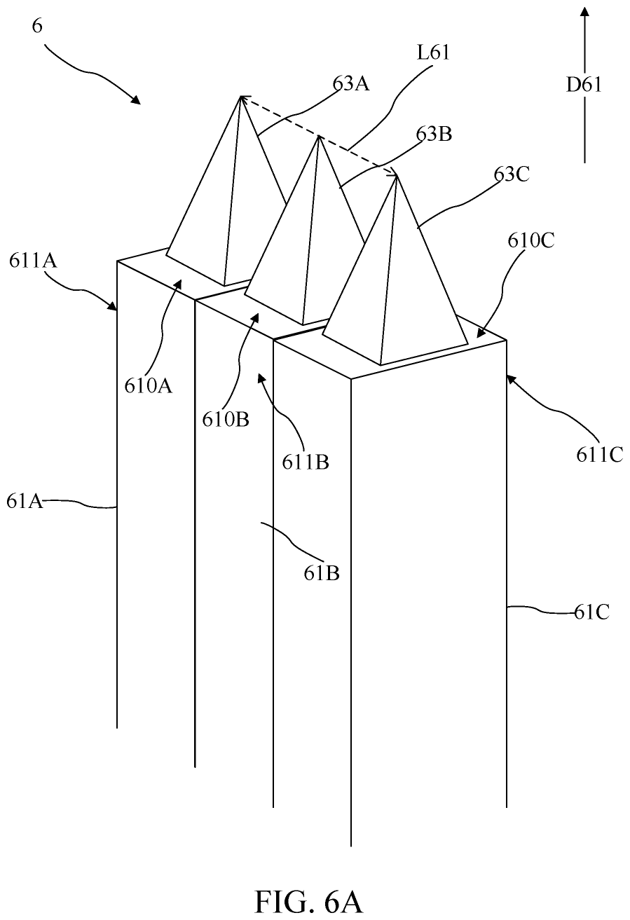

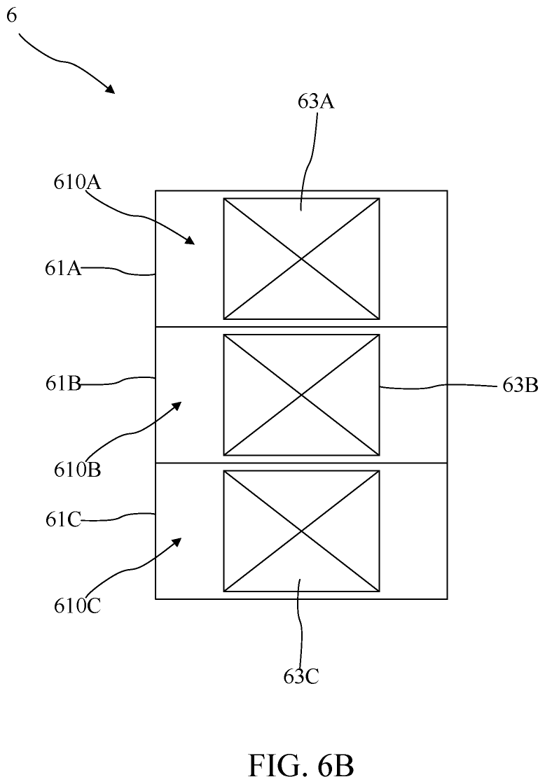

Referring to FIG. 6A and FIG. 6B, FIG. 6A is a perspective view of a probe structure 6 according to some embodiments of the present disclosure, and FIG. 6B is a top view of the probe structure 6 according to some embodiments of the present disclosure. The probe structure 6 comprises a first body 61A, a second body 61B, a third body 61C, a first protrusion 63A, a second protrusion 63B and a third protrusion 63C. The first body 61A comprises an end portion 611A. The end portion 611A has a surface 610A. The first protrusion 63A is formed on the surface 610A and extends in a direction D61. The second body 61B comprises an end portion 611B. The end portion 611B has a surface 610B. The second protrusion 63B is formed on the surface 610B and extends in the direction D61. The third body 61C comprises an end portion 611C. The end portion 611C has a surface 610C. The third protrusion 63C is formed on the surface 610C and extends in the direction D61. In some embodiments, the protrusions 63A, 63B and 63C are adapted to contact an object under test (not shown), for example, an IC chip.

In some embodiments, the first body 61A and the third body 61C are each contiguous with the second body 61B. A minimum distance between the first body 61A and the second body 61B is greater than or equal to zero, and is less than or equal to a specific numeric value. A minimum distance between the third body 61C and the second body 61B is greater than or equal to zero, and is less than or equal to a specific numeric value. In some embodiments, the minimum distance between the first body 61A and the second body 61B is equal to zero. In some embodiments, the minimum distance between the third body 61C and the second body 61B is equal to zero. In some embodiments, when the minimum distance between the first body 61A and the second body 61B is equal to a specific numeric value and the minimum distance between the third body 61C and the second body 61B is equal to a specific numeric value, a maximum width of the probe structure 6 is less than the structural width of conventional probe bodies.

In some embodiments, the vertices of the first protrusion 63A, the second protrusion 63B and the third protrusion 63C are colinear and define a line L61 parallel to the surfaces 610A, 610B and 610C. Thus, a shortest distance between the surface 610A and the vertex of the first protrusion 63A, a shortest distance between the surface 610B and the vertex of the second protrusion 63B, and a shortest distance between the surface 610C and the vertex of the third protrusion 63C are equal. The surface 610A, the surface 610B and the surface 610C are coplanar.

In some embodiments, toward to an opposite direction of the direction D61, a projection image of the line L61 falls on the surface 610A, the surface 610B and the surface 610C (i.e., the line L61 casts the projection image on the surface 610A, the surface 610B and the surface 610C). Thus, the projection image of the line L61 falls in a direction opposite to the direction D61 onto the surface 610A, the surface 610B and the surface 610C. Therefore, the projection image of the line L61 overlaps the surface 610A, the surface 610B and the surface 610C.

In some embodiments, when the probe structure 6 is adapted to contact a specific area to be tested on an object under test, a center of the line L61 defined by the vertices of the first protrusion 63A, the second protrusion 63B and the third protrusion 63C can be directed toward a center of the specific area to be tested, such that the center of the line L61 overlaps the center of the specific area to be tested. Therefore, when the first protrusion 63A, the second protrusion 63B and the third protrusion 63C of the probe structure 6 contact the specific area to be tested, a force exerted on the probe structure 6 due to the contact is evenly distributed between the first protrusion 63A, the second protrusion 63B and the third protrusion 63C.

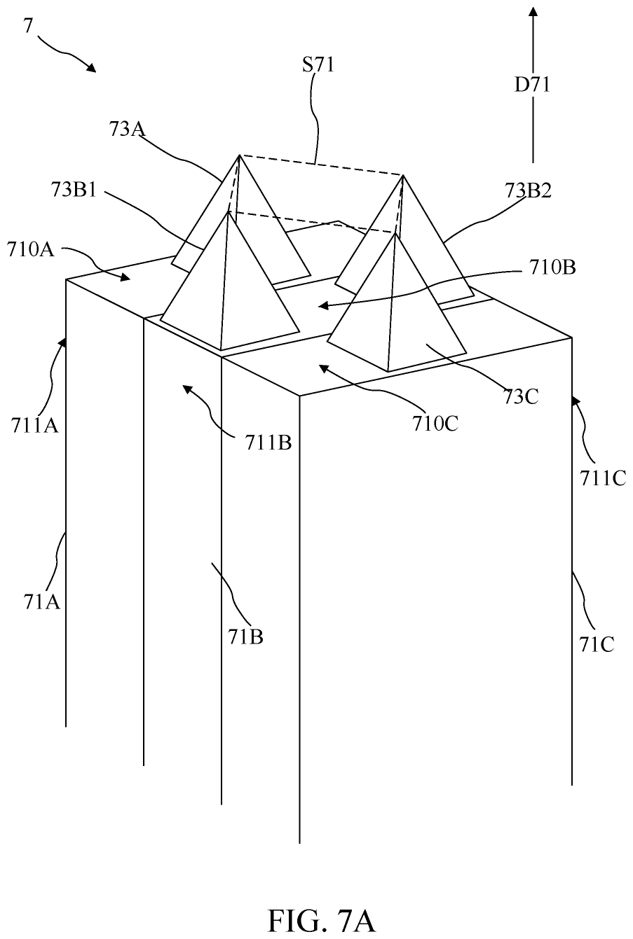

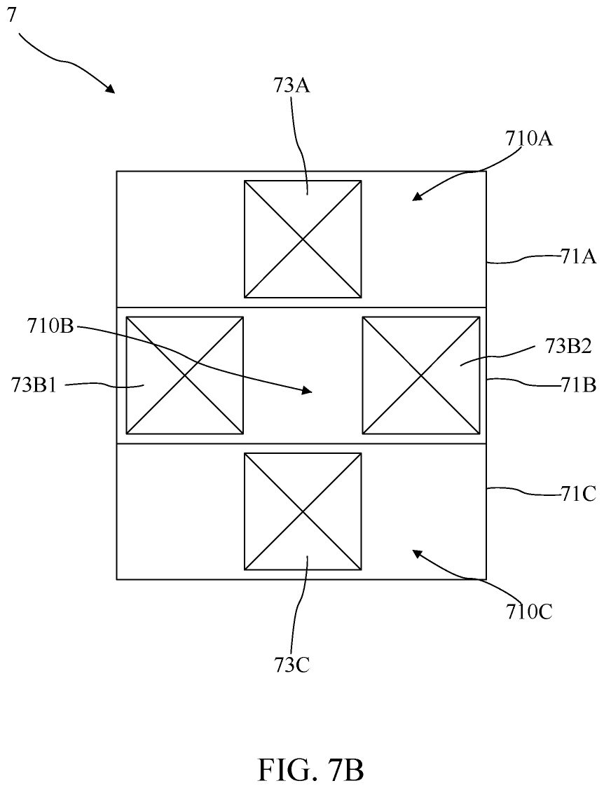

Referring to FIG. 7A and FIG. 7B, FIG. 7A is a perspective view of a probe structure 7 according to some embodiments of the present disclosure, and FIG. 7B is a top view of the probe structure 7 according to some embodiments of the present disclosure. The probe structure 7 comprises a first body 71A, a second body 71B, a third body 71C, a first protrusion 73A, a second protrusion 73B1, a third protrusion 73B2 and a fourth protrusion 73C. The first body 71A comprises an end portion 711A. The end portion 711A has a surface 710A. The first protrusion 73A is formed on the surface 710A and extends in a direction D71. The second body 71B comprises an end portion 711B. The end portion 711B has a surface 710B. The second protrusion 73B1 and the third protrusion 73B2 are formed on the surface 710B and extend in the direction D71. The third body 71C comprises an end portion 711C. The end portion 711C has a surface 710C. The third protrusion 73C is formed on the surface 710C and extends in the direction D71. In some embodiments, the protrusions 73A, 73B1, 73B2 and 73C are adapted to contact an object under test (not shown), for example, an IC chip.

In some embodiments, the first body 71A and the third body 71C are each contiguous with the second body 71B. A minimum distance between the first body 71A and the second body 71B is greater than or equal to zero, and is less than or equal to a specific numeric value. A minimum distance between the third body 71C and the second body 71B is greater than or equal to zero, and is less than or equal to a specific numeric value. In some embodiments, the minimum distance between the first body 71A and the second body 71B is equal to zero, and the minimum distance between the third body 71C and the second body 71B is equal to zero. In some embodiments, when the minimum distance between the first body 71A and the second body 71B is equal to a specific numeric value and the minimum distance between the third body 71C and the second body 71B is equal to a specific numeric value, a maximum width of the probe structure 7 is less than the structural width of conventional probe bodies.

In some embodiments, the vertices of the first protrusion 73A, the second protrusion 73B1, the third protrusion 73B2 and the fourth protrusion 73C are coplanar and define a plane S71 parallel to the surfaces 710A, 710B and 710C. Thus, a shortest distance between the surface 710A and the vertex of the first protrusion 73A, a shortest distance between the surface 710B and the vertex of the second protrusion 73B1, a shortest distance between the surface 710B and the vertex of the third protrusion 73B2, and a shortest distance between the surface 710C and the vertex of the fourth protrusion 73C are equal. The surface 710A, the surface 710B and the surface 710C are coplanar.

In some embodiments, toward to an opposite direction of the direction D71, a projection image of the plane S71 falls on the surface 710A, the surface 710B and the surface 710C (i.e., the plane S71 casts the projection image on the surface 710A, the surface 710B and the surface 710C). Thus, the projection image of the line S71 falls in a direction opposite to the direction D71 onto the surface 710A, the surface 710B and the surface 710C. Therefore, the projection image of the plane S71 overlaps the surface 710A, the surface 710B and the surface 710C.

In some embodiments, when the probe structure 7 is adapted to contact a specific area to be tested on an object under test, a center of the plane S71 defined by the vertices of the first protrusion 73A, the second protrusion 73B1, the third protrusion 73B2 and the fourth protrusion 73C can be directed toward a center of the specific area to be tested, such that the center of the plane S71 overlaps the center of the specific area to be tested. Therefore, when the first protrusion 73A, the second protrusion 73B1, the third protrusion 73B2 and the fourth protrusion 73C of the probe structure 7 contact the specific area to be tested, a force exerted on the probe structure 7 due to the contact is evenly distributed between the first protrusion 73A, the second protrusion 73B1, the third protrusion 73B2 and the fourth protrusion 73C.

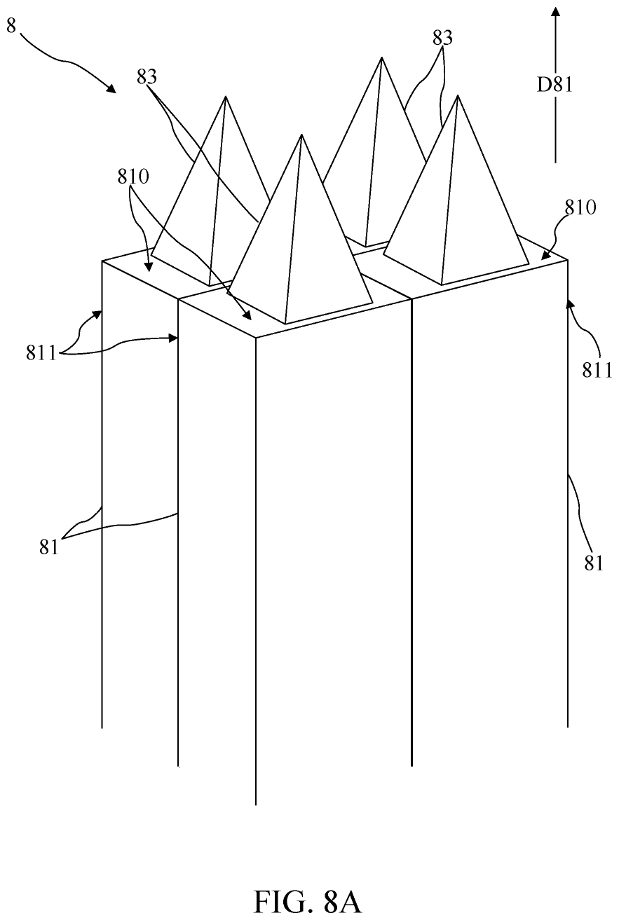

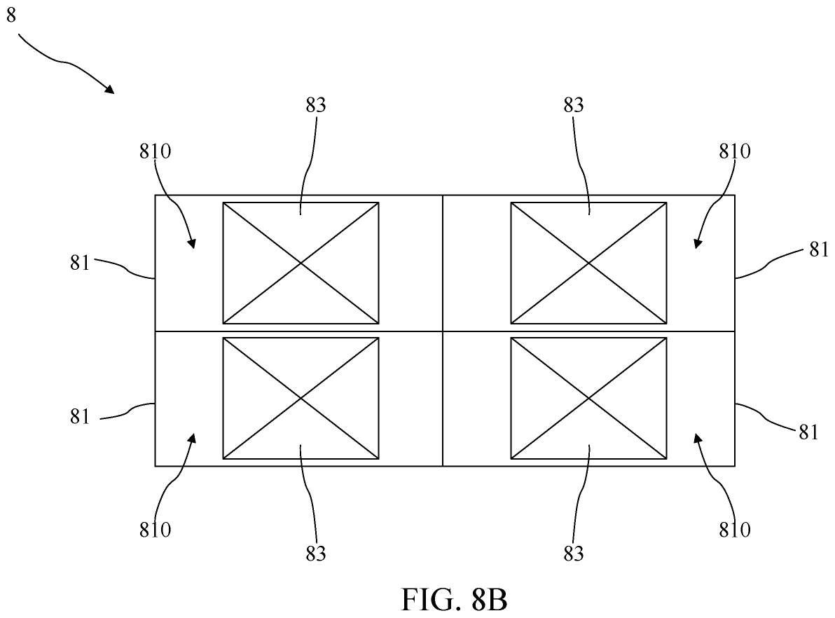

Referring to FIG. 8A and FIG. 8B, FIG. 8A is a perspective view of a probe structure 8 according to some embodiments of the present disclosure, and FIG. 8B is a top view of the probe structure 8 according to some embodiments of the present disclosure. The probe structure 8 comprises a plurality of bodies 81 and a plurality of protrusions 83. Each body 81 comprises an end portion 811 with a surface 810. Each of the plurality of protrusions 83 is formed on the surface 810 and extends in a direction D81. At least one protrusion 83 is formed on each surface 810. In some embodiments, each protrusion 83 is adapted to contact an object under test (not shown), for example, an IC chip.

In some embodiments, each body 81 is contiguous with at least two bodies 81. For instance, as shown in the diagrams, each body 81 has four sides, and two of the four sides are contiguous with two other bodies 81, respectively.

The protrusions in the above embodiments can be tapered in shape, and each protrusion can have a sharp end for perforating an oxidized film on an electrode surface of an object under test, so as to ensure good electrical contact. Each protrusion extends in a direction substantially perpendicular to a corresponding one of the surfaces.

The present disclosure and the advantages thereof are described in detail as above. However, it should be understood that various modifications, replacements and substitutions can be made without departing from the spirit and scope of the present disclosure as defined by the appended claims. For example, various processes above may be implemented by different approaches, and other processes or a combination thereof may be used in substitution for the various processes above.

Moreover, the scope of the present application is not limited to specific embodiments of the processes, machines, manufacture, substance composition, means, methods or steps given in the detailed description. A person skilled in the art could understand from disclosure of the present application that existing or future developed processes, machines, manufacture, substance compositions, means, methods or steps that achieve the same functions or achieve substantially the same results corresponding to those of the embodiments described in the disclosure can be utilized. Accordingly, such processes, machines, manufacture, substance compositions, means, methods and steps are to be encompassed within the scope of the appended claims.

1. A probe structure, comprising:
a plurality of bodies, each comprising an end portion with a surface; and
a plurality of protrusions formed on the surfaces and extending in a same direction, wherein at least one protrusion is formed on each surface.

2. The probe structure of claim 1, wherein the plurality of bodies include a first body and a second body contiguous with the first body.

3. The probe structure of claim 2, wherein the plurality of protrusions include a first protrusion and a second protrusion, the first protrusion is formed on the surface of the end portion of the first body, and the second protrusion is formed on the surface of the end portion of the second body.

4. The probe structure of claim 2, wherein the plurality of protrusions include a first protrusion, a second protrusion and a third protrusion, the first protrusion is formed on the surface of the end portion of the first body, the second protrusion is formed on the surface of the end portion of the second body, and the third protrusion is formed on the surface of the end portion of the second body.

5. The probe structure of claim 2, wherein the plurality of protrusions include a first protrusion, a second protrusion, a third protrusion and a fourth protrusion, the first protrusion and the second protrusion are formed on the surface of the end portion of the first body, and the third protrusion and the fourth protrusion are formed on the surface of the end portion of the second body.

6. The probe structure of claim 1, wherein the plurality of bodies include a first body, a second body and a third body, and the first body, the second body and the third body are contiguous with each other.

7. The probe structure of claim 1, wherein the plurality of bodies include a first body, a second body and a third body, and the first body and the second body are each contiguous with the third body.

8. The probe structure of claim 6, wherein the plurality of protrusions include a first protrusion, a second protrusion, a third protrusion and a fourth protrusion, the first protrusion is formed on the surface of the end portion of the first body, the second protrusion is formed on the surface of the end portion of the second body, the third protrusion is formed on the surface of the end portion of the third body, and the fourth protrusion is formed on the surface of the end portion of the third body.

9. The probe structure of claim 1, wherein each body is contiguous with at least two bodies.

10. The probe structure of claim 1, wherein each protrusion has a sharp end.

11. The probe structure of claim 10, wherein vertices of the sharp ends of the plurality of protrusions define a plane, and the plane is parallel to one or more of the surfaces.

12. The probe structure of claim 1, wherein each protrusion extends in a direction perpendicular to a corresponding one of the surfaces.

13. A probe structure, comprising:
a first body having a first contact end with a first surface;
a second body having a second contact end with a second surface;
at least a first sharp end formed on the first surface and extending in a direction; and
at least a second sharp end formed on the second surface and extending in the direction,
wherein a vertex of the at least a first sharp end and a vertex of the at least a second sharp end are colinear or coplanar, and a line or a plane defined by the vertex of the at least a first sharp end and the vertex of the at least a second sharp end is parallel to the first surface and the second surface.

14. The probe structure of claim 13, wherein, toward to an opposite direction of the direction, the line or the plane casts a projection image on the first surface and the second surface, and the projection image overlaps at least part of the first surface and the second surface.

15. The probe structure of claim 13, wherein the first body and the second body are contiguous.
